(19) United States
(12) Patent Application Publication
(10) Pub. No.: US 2017/0047772 A1
(43) Pub. Date: Feb. 16, 2017

(54) SYSTEM AND METHODS FOR DISTRIBUTED UNINTERRUPTABLE POWER SUPPLIES

(71) Applicant: SCHNEIDER ELECTRIC IT CORPORATION, West Kingston, RI (US)

(72) Inventors: Jian Wang, Beijing (CN); Wei-Shih Chiang, Shanghai (CN)

(21) Appl. No.: 15/303,621

(22) PCT Filed: Apr. 18, 2014
(86) PCT No.: PCT/CN2014/075711

§ 371 Date: Oct. 12, 2016

(51) Int. Cl. H02J 9/06; H02J 7/00; H05K 7/14; G06F 1/18; G06F 1/30

(52) U.S. Cl. CPC H02J 9/061; G06F 1/189; G06F 1/30; H05K 7/1492; H02J 7/0021

(57) ABSTRACT

According to one aspect, a distributed uninterruptible power supply (UPS) for mounting in a data center rack is provided. The distributed power system includes an input constructed to receive alternating current (AC) input power, an AC bus coupled to the input, a DC bus constructed to couple to at least one DC load in the data center rack, a battery bus coupled to at least one battery, and at least one power module. The at least one power module has a first input coupled to the AC bus, a second input coupled to the battery bus, and an output coupled to the DC bus and is constructed to generate DC power based on received power from at least one of the AC bus and the battery bus.

### BACKGROUND

Technical Field

Embodiments of the present disclosure relate generally to distributed uninterruptable power supplies (UPS), and more particularly, to distributed UPSs in data centers.

Background Discussion

UPSs provide reliable power to an external load by isolating the external load from power disturbances including, for example, power surges, sags, glitches, blackouts, and brownouts. UPSs isolate an external load from power disturbances by deriving output power from two or more power sources. The external load may include one or more components of a data center. UPSs in data centers are generally centralized online UPSs that convert alternating current (AC) power to direct current (DC) power and subsequently convert the DC power back to AC power. The output AC power from the UPS is subsequently distributed to various data center components that convert the received AC power into DC power at various voltages via one or more power supplies.

### SUMMARY

According to one aspect, a distributed uninterruptible power supply (UPS) for mounting in a data center rack is provided. The distributed power system comprises an input constructed to receive alternating current (AC) input power, an AC bus coupled to the input, a DC bus constructed to couple to at least one DC load in the data center rack, a battery bus coupled to at least one battery, and at least one power module. The at least one power module has a first input coupled to the AC bus, a second input coupled to the battery bus, and an output coupled to the DC bus and is constructed to generate DC power based on received power from at least one of the AC bus and the battery bus.

In one embodiment, the at least one power module includes a power module DC bus, a converter coupled between the first input of the at least one power module and the power module DC bus, and a first DC/DC converter coupled between the power module DC bus and the output of the at least one power module. In one embodiment, the power module further includes a second DC/DC converter coupled between the power module DC bus and the second input of the at least one power module. In one embodiment, the power module further includes a power diode having a cathode terminal coupled to the power module bus and an anode terminal coupled to the second input. In one embodiment, the power module DC bus is coupled to the second input of the power module. In one embodiment, the converter is constructed to charge the at least one battery based on AC power received from the input.

In one embodiment, the distributed UPS further comprises a charger coupled between the AC bus and the battery bus, the charger constructed to charge the at least one battery based on AC power received from the AC bus.

In one embodiment, the distributed UPS further comprises a controller coupled to the DC bus, the AC bus, the battery bus, and the at least one power module, the controller configured to monitor distributed UPS status parameters. In one embodiment, the distributed UPS status parameters include at least one of a voltage level of the AC bus, a voltage level of the battery bus, and a voltage level of the DC bus. In one embodiment, the distributed UPS further comprises a display coupled to the controller, the display configured to display the UPS status parameters.

According to one aspect, a power module constructed to provide direct current (DC) power to an external DC load from at least one of an external alternating current (AC) power source and an external battery in a distributed uninterruptable power supply is provided. The power module comprises a first input constructed to couple to the external AC power source, a second input constructed to couple to the external DC power source, an output constructed to couple to the external DC load, a power module DC bus, a converter coupled between the first input and the DC bus, the converter constructed to generate DC power based on AC power received from the AC bus, and a DC/DC converter coupled between the power module DC bus and the output.

In one embodiment, the power module further comprises a DC/DC converter coupled between the second input and the power module DC bus.

In one embodiment, the power module further comprises a power diode having a cathode terminal coupled to the power module bus and an anode terminal coupled to the second input.

In one embodiment, the power module DC bus is coupled to the second input. In one embodiment, the external DC power source is a battery and the converter is further constructed to charge the battery.

According to one aspect, a method of providing direct current (DC) power to one or more DC loads in a data center rack via a distributed uninterruptable power supply (UPS) is provided. The method comprises receiving alternating current (AC) power from an external power source, distributing the received AC power to at least one power module via an AC bus, converting the received AC power to DC power via the at least one power module coupled to the AC bus, distributing battery power from a battery to the at least one power module via a battery bus, and providing output DC power to the one or more DC load in the data center rack derived from at least one of the received AC power and the battery power via the at least one power module.

In one embodiment, providing the output DC power includes converting the battery power from a first voltage level to a second voltage level.

In one embodiment, the method further comprises charging the battery coupled to the battery bus based on the received AC power via one of a charger coupled between the battery bus and the AC bus and the at least one power module coupled to the battery bus;

In one embodiment, the method further comprises monitoring distributed UPS status parameters via a controller coupled to the AC bus and the battery bus and displaying the distributed UPS parameters via a display coupled to the controller.

In one embodiment, the method further comprises installing the distributed UPS in a data center rack.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed subject matter. Particular references to examples and embodiments, such as “an embodiment,” “another embodiment,” “some embodiments,” “other embodiments,” “an alternate embodiment,” “various embodiments,” “one embodiment,” “at least one embodiments,” “this and other embodiments” or the like, are not necessarily mutually exclusive and are intended to indicate that a particular feature, structure, or characteristic described in connection with the embodiment or example and may be included in that embodiment or example and other embodiments or examples. The appearances of such terms herein are not necessarily all referring to the same embodiment or example.

Furthermore, in the event of inconsistent usages of terms between this document and documents incorporated herein by reference, the term usage in the incorporated references is supplementary to that of this document; for irreconcilable inconsistencies, the term usage in this document controls. In addition, the accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of an example data center;

FIG. 2 illustrates a perspective view of an example rack;

FIG. 3 illustrates a block diagram of an example rack including a distributed UPS;

FIGS. 4A-C illustrate diagrams of example distributed UPS power modules;

FIG. 5 illustrates an example module arrangement in a rack including a distributed UPS;

FIG. 6 illustrates a flow diagram of one example method of operation for a distributed UPS; and

FIG. 7 illustrates a block diagram of one example of a computer system upon which various aspects of the present embodiments may be implemented.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated references is supplementary to that of this document; for irreconcilable inconsistencies, the term usage in this document controls.

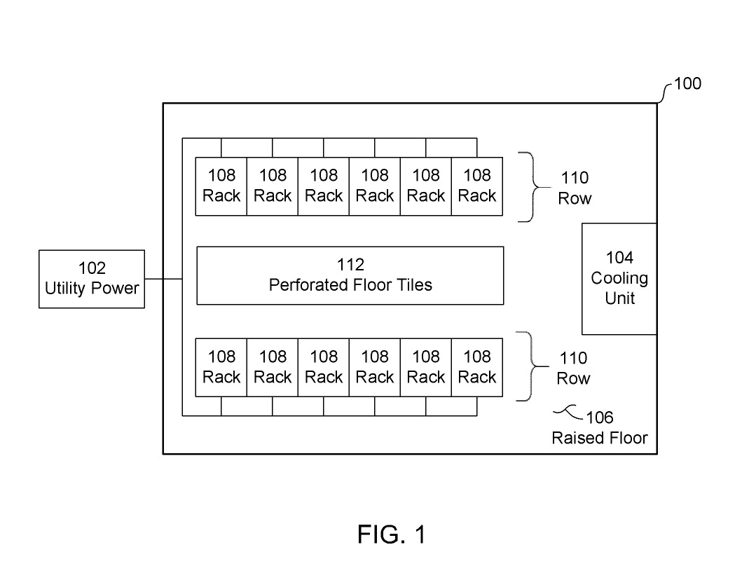

As discussed above, data centers traditionally employ centralized online UPSs to provide reliable power to various data center components. Online UPSs convert received AC power to DC power and subsequently convert the DC power back to AC power. The AC power output by the centralized online UPS is provided to various data center components (e.g., a server) that typically convert the received AC power back to DC power at various voltage levels via a power supply (e.g., a server power supply). Each power conversion process from AC power to DC power or vice versa produces power losses and thereby reduces power efficiency. Accordingly, some embodiments include distributed UPSs that reduce the number of necessary power conversion processes between the AC power received from, for example, a power grid and the DC power provided to various data center components. An example data center is described below with reference to FIG. 1.

### Example Data Center

Embodiments of distributed UPSs described herein may be used in the design or retrofitting of a data center, such as data center 100, which is illustrated in FIG. 1. Data center 100 may include various resources, equipment, or devices that support or ensure data center equipment functionality. Examples of data center 100 resources include power, cooling, physical space, weight support, remote equipment control capability, physical and logical security and physical and logical network connectivity. Power data center resources may include power distribution resources, such as transformers, power distribution units, outlets, and power available for distribution, such as utility power 102 supplied to data center 100, power generated by an onsite generator and power supplied by power distribution units. Physical space resources in data center 100 may include data center floor space and rack U space. Cooling resources in data center 100 may include cooling distribution capacity and cooling generation capacity. Physical security resources in data center 100 may include security cameras and door locks. Logical network connectivity resources in data center 100 may include Virtual Local Area Networks, Domain Name Services, and Dynamic Host Configuration Protocol Services. Physical network connectivity resources may include network cabling and patch panels. Remote equipment control capability resources in data center 100 may include Keyboard Video Mouse services.

Data center 100 is a representative data center and various embodiments described herein are not limited to data centers such as data center 100. Various other data centers and facilities may be used that, for example, do not include raised floors 106. Data center 100 or other data centers may be used with facilities that house more, less, or different equipment, or equipment other than computing equipment, including telecommunications facilities and other facilities. In one embodiment, data center 100 includes a computer supported by a subsystem. Data center 100 may, but need not be a dedicated space or room. Further, data center equipment layouts need not be neatly arranged as illustrated in FIG. 1.

Data center 100 includes rows 110, cooling unit 104, and at least one raised floor 106. Rows 110 include at least one rack 108, which in operation can draw cool air from the front of rack 108 and return warm air to the rear or top of rack 108. In one embodiment, rack 108 contains U space positions designed to house rack mounted data center equipment, such as, for example, servers, computers, cooling equipment, or network connectivity equipment.

In one embodiment, perforated floor tiles 112 can be used to provide cooling air from under raised floor 106. In data center 100, in addition to the perforated floor tiles 112, raised floor 106 may include solid floor tiles. Cooling units 104 can provide cool air to the area under raised floor 106 and can receive warm air from a space adjacent the ceiling of the data center. Cooling units 104 can also exhaust cool air toward the ceiling of the data center, and intake warm air from the floor of the data center.

In one embodiment, in addition to or in place of cooling units 104, in-row cooling units, such as those available from American Power Conversion (APC) Corporation of West Kingston, R.I. may be used. In one embodiment, half-rack in-row cooling units may be used with, for example, a width of twelve inches, which is approximately half of that of a standard data center rack.

Data centers 100 may include a plurality of different types of servers. For example, a server may be a physical server, a dedicated server, or a virtual server. A physical server generally includes hardware on which an operating system is run. A dedicated server generally includes a service application running on a physical server. For example, a dedicated server may include a web service or file transfer protocol (FTP) service on an operating system, where the service application can be coupled to the physical server. A virtual server can include a service that is independent of physical server hardware. For example, a virtual server may include a partitioning of a physical server into multiple servers, each having the appearance and capabilities as if they were running on their own dedicated server. In one embodiment, there can be one dedicated server operating system per physical server and multiple virtual servers per physical server. A virtual server can run concurrent with (e.g., on top of) a dedicated server. A plurality of servers or racks 108 may form a cluster to collectively run applications or programs. The cluster can have at least one dedicated cooling unit 104, or multiple clusters can share the same cooling unit 104.

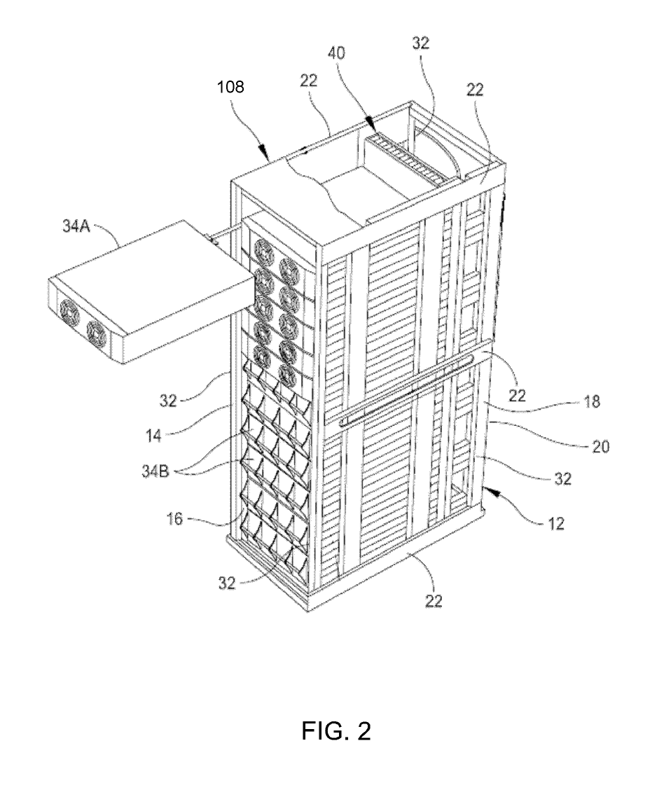

FIG. 2 illustrates an example rack 108 having a frame assembly 12 that includes a front frame 14, which defines a front 16 of the rack, and a rear frame 18, which defines a rear 20 of the rack. The frame assembly 12 further includes several side frame members, each indicated at 22, which connect the front frame 14 to the rear frame 18. The front frame 14 and the rear frame 18 include vertical rails, each indicated at 32. The rack 108 is illustrated as a “four post” rack, having four vertical rails or posts 32 placed at the four corners of the rack.

The rack 108 is configurable to accommodate equipment having a variety of shapes and sizes. In at least one embodiment, the equipment rack 108 may be configured to be the same size and shape as a nineteen-inch rack. In some embodiments, rack 108 has a universal interface for receiving all types of standardized modules, which are rack-mounted at the front and/or at the rear of the rack. In these embodiments, the front 16 of the rack 108 is configured to be deeper to receive larger modules and the rear 20 of the rack 108 is configured to be shallower to receive smaller modules.

As shown in FIG. 2, several modules 34A and 34B are rack-mounted in the front 16 of the rack 108 and are positioned in stacked relation (i.e., one over the other) near the top of the rack 108. A single module 34A is shown in a position in which it is being inserted into or removed from the rack 108. In one embodiment, the modules 34A and 34B are supported by slide rails (not shown) within the interior of the rack 108. The modules 34A and 34B may comprise various components including, for example, server equipment, cooling equipment, network connectivity equipment, and/or power equipment. The rack 108 may be configured to store the modules 34A and 34B in other arrangements and is not limited to a vertical stack arrangement.

In some embodiments, the rack 108 includes a busbar backplane, generally indicated at 40, to electrically connect the modules 34A and 34B mounted within the rack 108. The busbar backplane 40 is disposed between the front frame 14 and the rear frame 18 in the rack 108. The busbar backplane 40 may be positioned anywhere within the interior of the rack 108.

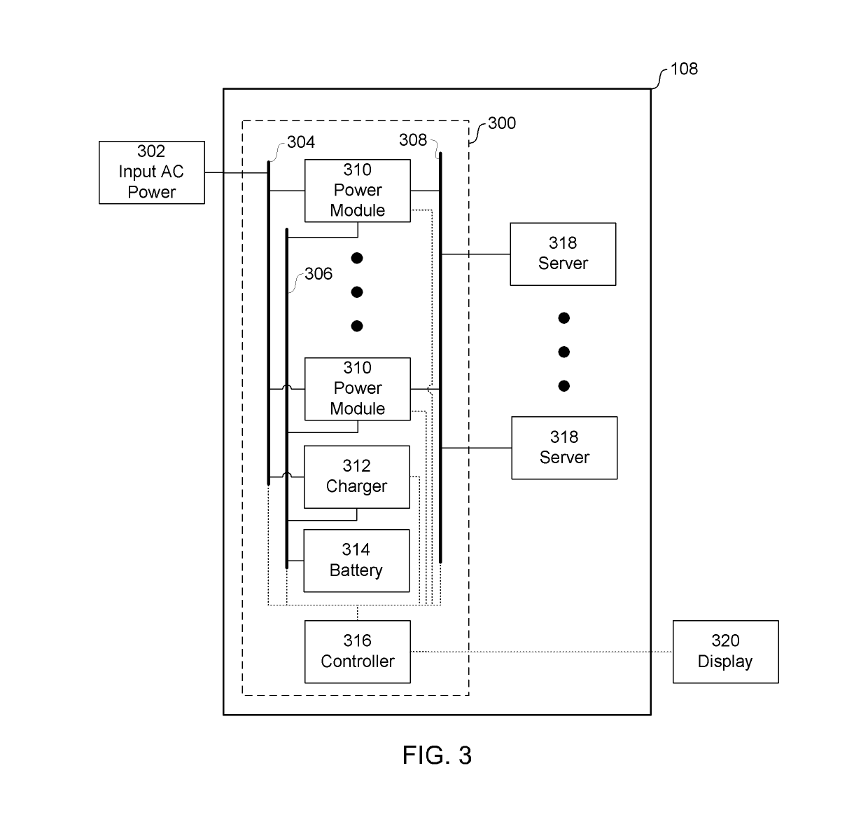

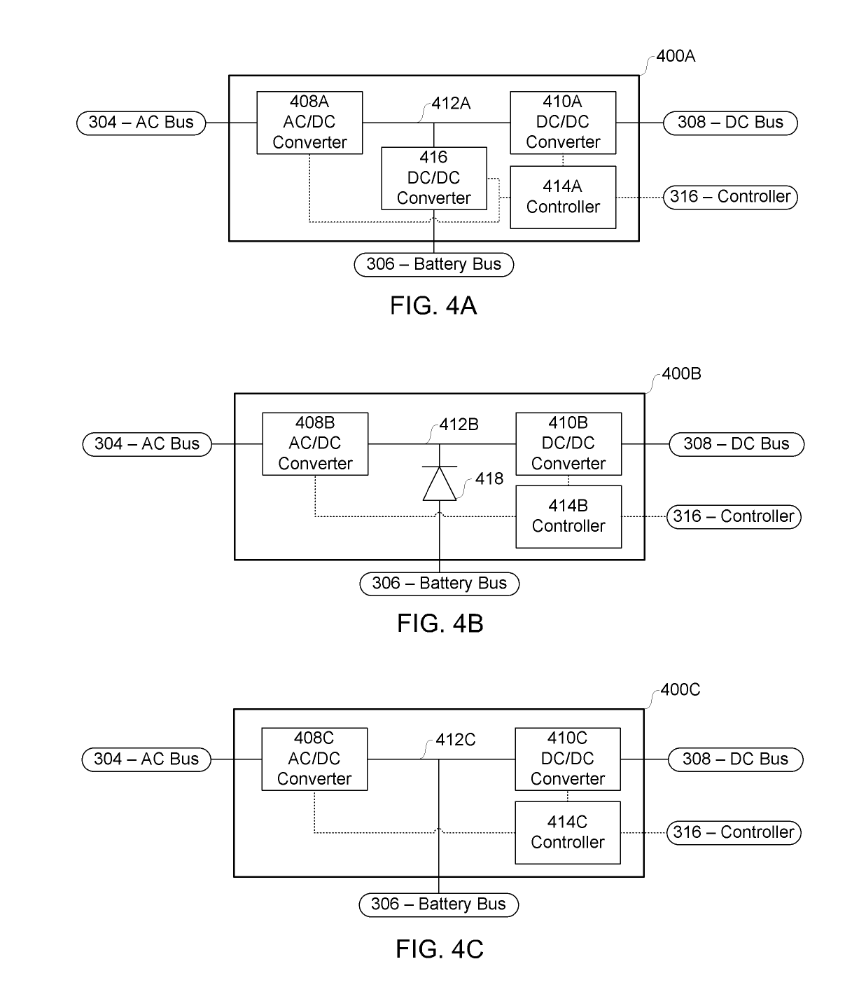

Although various embodiments and examples discussed herein relate to distributed UPSs in data centers, embodiments of the distributed UPSs are not limited to use in data centers and may be used in other types of facilities. Various embodiments of distributed UPSs are described below with reference to FIGS. 3 and 4A-4C.

### Example Distributed Uninterruptable Power Supply

FIG. 3 is a block diagram of a rack 108 including a distributed UPS 300 according to some aspects and embodiments disclosed herein. The distributed UPS 300 is constructed to receive AC input power 302, provide DC output power to one or more servers 318, and optionally output various parameters to display 320 and/or an external monitoring system. The distributed UPS 300 includes an AC bus 304, a battery bus 306, a DC bus 308, power modules 310, a charger 312, a battery 314, and a controller 316. The distributed UPS 300 may be organized into one or more rack-mounted modules (e.g., modules 34A and 34B) to facilitate installation of the distributed UPS 300 in a rack 108. In one embodiment, the rack 108 and/or the distributed UPS 300 are provided in the form of a kit, which can be easily assembled with the use of simple tools (e.g., a screwdriver), if any, and without difficult manipulation.

The distributed UPS 300 is constructed to receive input AC power 302 from an external AC power source such as a utility power source. The input AC power 302 is distributed to various components within the distributed UPS 300 via an AC bus 304. The AC bus 304 is coupled to one or more power modules 310 and the charger 312. The charger 312 receives AC power from the AC bus 304 and charges a battery 314 coupled to the charger 312 via the battery bus 306. The charger 312 may be omitted from the distributed UPS 300 and the battery charging operation may be performed by power module 310 as described below with reference to power module 400C in FIG. 4C.

The controller 316 is coupled to each of the AC bus 304, the battery bus 306, the DC bus 308, the power module 310, charger 312, and optionally display 320. In one embodiment, the controller 316 is configured to monitor various parameters of the distributed UPS 300 including, for example, power module status, charger module status, alarm or alert messages, voltage levels and/or current magnitudes on the AC bus 304, the battery bus 306, and/or the DC bus 308. The monitored distributed UPS information may be transmitted to display 320 or to an external monitoring system to present distributed UPS status parameters to, for example, a technician. The controller may be further configured to direct distributed UPS 300 to charge and/or discharge the battery 314.

The power module 310 is coupled to each of the AC bus 304, the battery bus 306, and the DC bus 308. In one embodiment, the power module 310 is constructed to operate in one or more modes of operation based on the quality of the AC power received from the AC bus 304. The mode of operation may include, for example, a first mode where the output DC power is generated based on AC power received from AC bus 304 and a second mode where the output DC power is generated based on DC power received from the battery bus 306 or a combination of power received from the AC bus 304 and the battery bus 306. In this embodiment, the power module 310 monitors the AC power received from the AC bus 304 and, based on the monitored AC power, determines an appropriate mode of operation. The power module may be constructed to normally operate in the first mode and provide DC output power to the DC bus 308 based on AC power received from AC bus 304. In the event that the quality of power received from the AC bus 304 deteriorates, the power module 310 may switch from operating in the first mode to operating in the second mode and draw power from the battery bus 306 to supplement and/or replace the power received from AC bus 304. Example power modules 310 are further described below with reference to power modules 400A-400C in FIGS. 4A-4C.

FIGS. 4A-4C illustrate various embodiments of power modules 400A-400C coupled to each of the AC bus 304, the battery bus 306, and the DC bus 308 that may be employed as power module 310 described above with reference to FIG. 3. Power module 400A as illustrated in FIG. 4A includes an AC/DC converter 408A, a DC/DC converter 410A, power module DC bus 412A, controller 414A, and DC/DC converter 416.

The AC/DC converter 408A is coupled between the AC bus 304 and the power module DC bus 412A and constructed to convert received AC power from AC bus 304 to DC power for the power module DC bus 412A. The AC/DC converter 408A may also include power factor correction (PFC) circuitry to, for example, improve the power factor.

The DC/DC converter 416 is coupled between the battery bus 306 and power module DC bus 412A and constructed to convert DC power received from battery bus 306 at a first voltage level to DC power at a second voltage level for the power module DC bus 412A. For example, the battery bus 306 may have a voltage level of 240 Volts and the power module DC bus may have a voltage level of 400 Volts.

The DC/DC converter 410A is coupled between the power module DC bus 412A and DC bus 308. The DC/DC converter is constructed to convert DC power from the power module DC bus 412A at the second voltage level to DC power at a third voltage level for the DC bus 308. For example, the power module DC bus 412A may have a voltage level of 400 Volts and the DC bus may have a voltage level of 12 Volts.

The controller 414A is coupled to each of the AC/DC converter 408A, the DC/DC converter 410A, the DC/DC converter 416, and controller 316. The controller 414A may be constructed to control the operation of power module 400A. For example, the controller 414A may output one or more switching commands to any combination of the AC/DC converter 408A, the DC/DC Converter 410A, and the DC/DC converter 416 to facilitate power conversion processes. The controller 414A may provide power module status information to controller 316. The controller 316 may generate power module status, alarm, or alert messages based on the received power module status information. The power module status, alarm, or alert messages may subsequently be displayed to, for example, a technician as previously described with reference to FIG. 3.

In some embodiments, the controller 414A may control a mode of operation of the power module 400A. The modes of operation may include, for example, a mains mode where the output DC power is generated based on AC power received from AC bus 304 and a battery mode where the output DC power is generated based on DC power received from the battery bus 306 or a combination of power received from the AC bus 304 and the battery bus 306. The controller 414A may control the mode of operation based on the quality of power received from AC bus 304. For example, the controller 414A may switch from operating in the mains mode of operation to the battery mode of operation responsive to the power quality from AC bus 304 deteriorating.

FIG. 4B illustrates power module 400B that includes AC/DC converter 408B, DC/DC converter 410B, power module DC bus 412B, controller 414B, and power diode 418. The AC/DC converter 408B, the DC/DC converter 410B, the power module DC bus 412B, and the controller 414B may be substantially similar to the AC/DC converter 408A, the DC/DC converter 410A, the power module DC bus 412A, and the controller 414A described above with reference to power module 400A in FIG. 4A. Power module 400B employs a power diode 418 coupled between the power module DC bus 412B and the battery bus 306. In one embodiment, the power diode 418 has a cathode terminal coupled to the power module bus and an anode terminal coupled to the second input. In this embodiment, power is provided to the power module DC bus 412B from the battery bus 306 as the voltage level of the power module DC bys 412B falls below the voltage level of the battery bus 306. The power diode 418 assists in maintaining a relatively consistent voltage level at the power module DC bus 412B regardless of the quality of the power received from AC bus 304. For example, the AC source supplying the AC power to the AC bus 304 may fail and thereby cause the voltage level of the power module DC bus to dip as the power module 400B continues to supply power to the DC bus 308. In this example, the voltage dip may cause the power diode 418 to start conducting and thereby allow power from the battery bus 306 to be supplied to the power module DC bus 412B.

FIG. 4C illustrates power module 400C that includes AC/DC converter 408C, DC/DC converter 410C, power module DC bus 412C, and controller 414C. Power module 400C illustrated in FIG. 4C may perform the functions of both the power module 310 and the charger 312 described above with reference to FIG. 3. In this embodiment, power module DC bus 412C is directly coupled to the battery bus 306. The AC/DC converter 408C coupled between the AC bus 304 and the battery bus 306 both provides power to the power module bus 412C for conversion by DC/DC converter 410C in addition to charging a battery coupled to the battery bus 306 (e.g., battery 314). The DC/DC converter 410C and the controller 414C may be substantially similar to the DC/DC converter 410A and the controller 414A described above with reference to power module 400A in FIG. 4A.

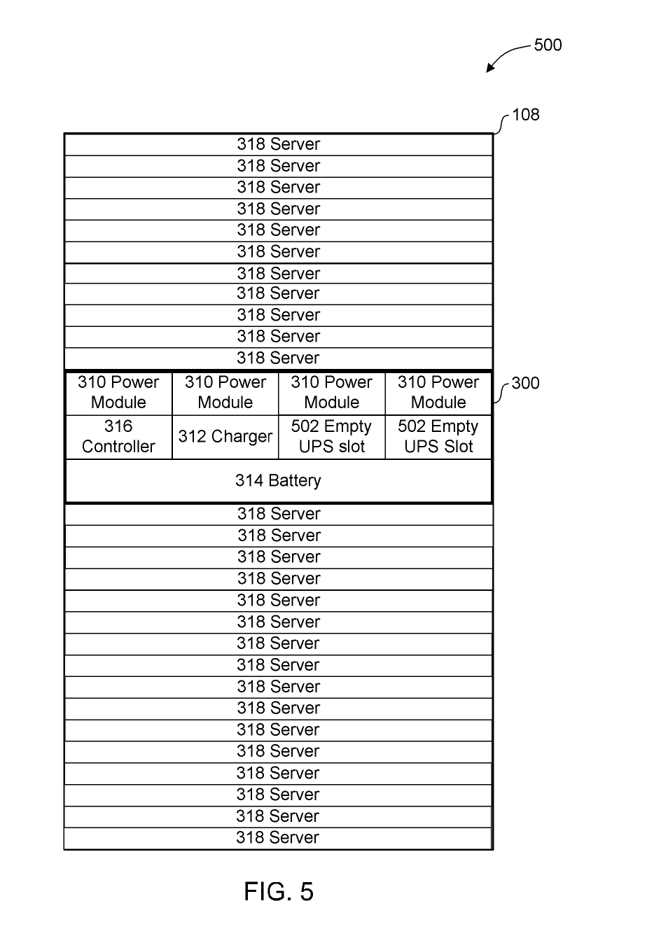

FIG. 5 illustrates an example module arrangement 500 in a rack 108 including distributed UPS 300. The module arrangement 500 includes a plurality of server modules 318 mounted near the top and bottom of rack 108. Near the center of the rack 108, the module arrangement 500 includes various UPS modules associated with the distributed UPS 300 and empty UPS slots 502. The various UPS modules include a series of power modules 310, a controller 316, a charger 312, and a battery 314. The power module 310, controller 316, and charger 312 UPS modules may be hot swappable modules. Hot swappable modules are devices that may be installed and/or removed without shutting down distributed UPS 300.

The empty UPS slots 502 may be filled with, for example, additional power modules 310 to increase the parallel redundancy of distributed UPS 300. Other module arrangements and distributed UPS configurations may be employed in rack 108. For example, the distributed UPS 300 in rack 108 may employ two or more batteries 314 to increase the period of time that distributed UPS 300 may supply power in battery mode.

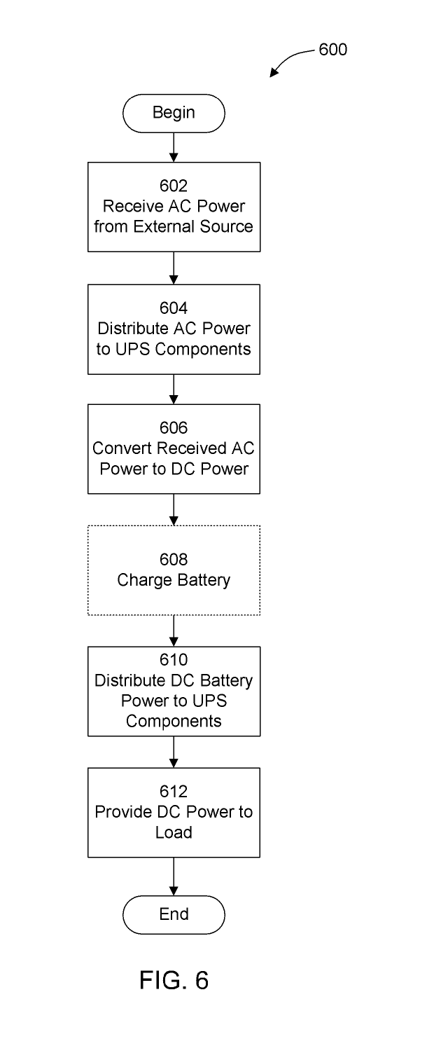

One or more processes may be performed by the distributed UPS 300 to provide reliable power to one or more DC loads in, for example, a data center. Example processes performed by the distributed UPS 300 to provide reliable power is described below with reference to FIG. 6.

### Example Distributed Uninterruptable Power Supply Processes

As described above with reference to FIGS. 3 and 4A-C, several embodiments illustrate distributed UPSs that decrease the number of power conversion steps required to provide DC power provided to various data center components based on AC power received from, for example, a power utility. Process 600 illustrates a method of operation for a distributed UPS.

In act 602, the distributed UPS receives AC power from an external source (e.g., a power grid). In act 604, the distributed UPS distributes AC power to various components within the distributed UPS. For example, the distributed UPS may distribute AC power to one or more power modules (e.g., power modules 310) and/or charger (e.g., charger 312) via an AC bus (e.g., AC bus 304).

In act 606, the distributed UPS converts the received AC power to DC power. The AC to DC conversion process may be performed by, for example, a converter in a power module of the distributed UPS (e.g., AC/DC converters 408A-C in power modules 400A-C).

In optional act 608, the distributed UPS charges a battery (e.g., battery 314). The distributed UPS may charge the battery via a charger (e.g., charger 312) and/or via an AC/DC converter in a power module (e.g., AC/DC converter 408C of power module 400C). The distributed UPS may, for example, perform optional act 608 responsive to a state-of-charge (SoC) parameter of the battery falling below a threshold.

In act 610, the distributed UPS distributes DC battery power to various components within the distributed UPS. The distributed UPS may distribute the battery power to one or more power modules (e.g., power modules 310) via a battery bus (e.g., battery bus 306).

In act 612, the distributed UPS provides DC power to the load. The distributed UPS may provide the DC power to the load derived from the AC power received in act 602 and/or the battery power. The distributed UPS may, for example, provide DC power to the load derived from the battery power responsive to the quality of the AC power received in act 602 being poor.

In embodiments described above, a distributed UPS system receives AC power. The input power may be single phase power or multiple phase power. Further in other embodiments, input DC power may be used. In embodiments described above backup DC power is provided by a battery. In other embodiments, backup DC power may be provided by other devices including, for example, fuel cell systems.

Furthermore, various aspects and functions described herein in accord with the present disclosure may be implemented as hardware, software, firmware or any combination thereof. Aspects in accord with the present disclosure may be implemented within methods, acts, systems, system elements and components using a variety of hardware, software or firmware configurations. Furthermore, aspects in accord with the present disclosure may be implemented as specially-programmed hardware and/or software.

### Example Computer System

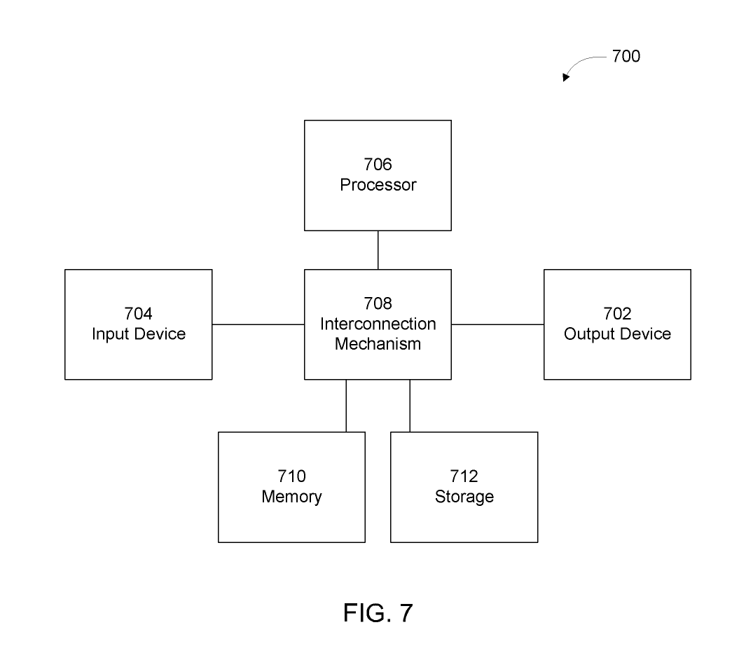

FIG. 7 illustrates an example block diagram of computing components forming a system 700 which may be configured to implement one or more aspects disclosed herein. For example, the system 700 may be communicatively coupled to a distributed UPS or included within a distributed UPS and configured to perform one or more acts within the distributed UPS processes as described above with reference to FIG. 6.

The system 700 may include for example a general-purpose computing platform such as those based on Intel PENTIUM-type processor, Motorola PowerPC, Sun UltraSPARC, Texas Instruments-DSP, Hewlett-Packard PA-RISC processors, or any other type of processor. System 700 may include specially-programmed, special-purpose hardware, for example, an application-specific integrated circuit (ASIC). Various aspects of the present disclosure may be implemented as specialized software executing on the system 700 such as that shown in FIG. 7.

The system 700 may include a processor/ASIC 706 connected to one or more memory devices 710, such as a disk drive, memory, flash memory or other device for storing data. Memory 710 may be used for storing programs and data during operation of the system 700. Components of the computer system 700 may be coupled by an interconnection mechanism 708, which may include one or more buses (e.g., between components that are integrated within a same machine) and/or a network (e.g., between components that reside on separate machines). The interconnection mechanism 708 enables communications (e.g., data, instructions) to be exchanged between components of the system 700. Further, in some embodiments the interconnection mechanism 708 may be disconnected during servicing of a PDU.

The system 700 also includes one or more input devices 704, which may include for example, a keyboard or a touch screen. An input device may be used for example to configure the measurement system or to provide input parameters. The system 700 includes one or more output devices 702, which may include for example a display. In addition, the computer system 700 may contain one or more interfaces (not shown) that may connect the computer system 700 to a communication network, in addition or as an alternative to the interconnection mechanism 708.

The system 700 may include a storage system 712, which may include a computer readable and/or writeable nonvolatile medium in which signals may be stored to provide a program to be executed by the processor or to provide information stored on or in the medium to be processed by the program. The medium may, for example, be a disk or flash memory and in some examples may include RAM or other non-volatile memory such as EEPROM. In some embodiments, the processor may cause data to be read from the nonvolatile medium into another memory 710 that allows for faster access to the information by the processor/ASIC than does the medium. This memory 710 may be a volatile, random access memory such as a dynamic random access memory (DRAM) or static memory (SRAM). It may be located in storage system 712 or in memory system 710. The processor 706 may manipulate the data within the integrated circuit memory 710 and then copy the data to the storage 712 after processing is completed. A variety of mechanisms are known for managing data movement between storage 712 and the integrated circuit memory element 710, and the disclosure is not limited thereto. The disclosure is not limited to a particular memory system 710 or a storage system 712.

The system 700 may include a general-purpose computer platform that is programmable using a high-level computer programming language. The system 700 may be also implemented using specially programmed, special purpose hardware, e.g. an ASIC. The system 700 may include a processor 706, which may be a commercially available processor such as the well-known Pentium class processor available from the Intel Corporation. Many other processors are available. The processor 706 may execute an operating system which may be, for example, a Windows operating system available from the Microsoft Corporation, MAC OS System X available from Apple Computer, the Solaris Operating System available from Sun Microsystems, or UNIX and/or LINUX available from various sources. Many other operating systems may be used.

The processor and operating system together may form a computer platform for which application programs in high-level programming languages may be written. It should be understood that the disclosure is not limited to a particular computer system platform, processor, operating system, or network. Also, it should be apparent to those skilled in the art that the present disclosure is not limited to a specific programming language or computer system. Further, it should be appreciated that other appropriate programming languages and other appropriate computer systems could also be used.

Having thus described several aspects of at least one example, it is to be appreciated that various alterations, modifications, and improvements will readily occur to those skilled in the art. For instance, examples disclosed herein may also be used in other contexts. Such alterations, modifications, and improvements are intended to be part of this disclosure, and are intended to be within the scope of the examples discussed herein. Accordingly, the foregoing description and drawings are by way of example only.

What is claimed is:

1. A distributed uninterruptible power supply (UPS) for mounting in a data center rack, the distributed power system comprising:
an input constructed to receive alternating current (AC) input power;
an AC bus coupled to the input;
a DC bus constructed to couple to at least one DC load in the data center rack;
a battery bus coupled to at least one battery; and
at least one power module having a first input coupled to the AC bus, a second input coupled to the battery bus, and an output coupled to the DC bus, the at least one power module constructed to generate DC power based on received power from at least one of the AC bus and the battery bus.

2. The distributed UPS of claim 1, wherein the at least one power module includes:
a power module DC bus;
a converter coupled between the first input of the at least one power module and the power module DC bus; and
a first DC/DC converter coupled between the power module DC bus and the output of the at least one power module.

3. The distributed UPS of claim 2, wherein the power module further includes a second DC/DC converter coupled between the power module DC bus and the second input of the at least one power module.

4. The distributed UPS of claim 2, wherein the power module further includes a power diode having a cathode terminal coupled to the power module bus and an anode terminal coupled to the second input.

5. The distributed UPS of claim 2, wherein the power module DC bus is coupled to the second input of the power module.

6. The distributed UPS of claim 5, wherein the converter is constructed to charge the at least one battery based on AC power received from the input.

7. The distributed UPS of claim 1, further comprising a charger coupled between the AC bus and the battery bus, the charger constructed to charge the at least one battery based on AC power received from the AC bus.

8. The distributed UPS of claim 1, further comprising a controller coupled to the DC bus, the AC bus, the battery bus, and the at least one power module, the controller configured to monitor distributed UPS status parameters.

9. The distributed UPS of claim 8, wherein the distributed UPS status parameters include at least one of a voltage level of the AC bus, a voltage level of the battery bus, and a voltage level of the DC bus.

10. The distributed UPS of claim 8, further comprising a display coupled to the controller, the display configured to display the UPS status parameters.

11. A power module constructed to provide direct current (DC) power to an external DC load from at least one of an external alternating current (AC) power source and an external battery in a distributed uninterruptable power supply, the power module comprising:
a first input constructed to couple to the external AC power source;
a second input constructed to couple to the external DC power source;
an output constructed to couple to the external DC load;
a power module DC bus;
a converter coupled between the first input and the DC bus, the converter constructed to generate DC power based on AC power received from the AC bus; and
a DC/DC converter coupled between the power module DC bus and the output.

12. The power module of claim 11, further comprising a DC/DC converter coupled between the second input and the power module DC bus.

13. The power module of claim 11, further comprising a power diode having a cathode terminal coupled to the power module bus and an anode terminal coupled to the second input.

14. The power module of claim 11, wherein the power module DC bus is coupled to the second input.

15. The power module of claim 14, wherein the external DC power source is a battery and the converter is further constructed to charge the battery.

16. A method of providing direct current (DC) power to one or more DC loads in a data center rack via a distributed uninterruptable power supply (UPS), the method comprising:
receiving alternating current (AC) power from an external power source;
distributing the received AC power to at least one power module via an AC bus;
converting the received AC power to DC power via the at least one power module coupled to the AC bus;
distributing battery power from a battery to the at least one power module via a battery bus; and
providing output DC power to the one or more DC load in the data center rack derived from at least one of the received AC power and the battery power via the at least one power module.

17. The method of claim 16, wherein providing the output DC power includes converting the battery power from a first voltage level to a second voltage level.

18. The method of claim 16, further comprising charging the battery coupled to the battery bus based on the received AC power via one of a charger coupled between the battery bus and the AC bus and the at least one power module coupled to the battery bus;

19. The method of claim 16, further comprising:
monitoring distributed UPS status parameters via a controller coupled to the AC bus and the battery bus; and
displaying the distributed UPS parameters via a display coupled to the controller.

20. The method of claim 16, further comprising installing the distributed UPS in a data center rack.
